(19) United States
(12) Patent Application Publication
(10) Pub. No.: US 2016/0071789 A1
(43) Pub. Date: Mar. 10, 2016

(54) MOLDED INTERPOSER FOR PACKAGED SEMICONDUCTOR DEVICE

(71) Applicants: Pei Fan Tong, Bkt Jalil (MY); Boon Yew Low, Petaling Jaya (MY); Lan Chu Tan, Singapore (SG)

(72) Inventors: Pei Fan Tong, Bkt Jalil (MY); Boon Yew Low, Petaling Jaya (MY); Lan Chu Tan, Singapore (SG)

(73) Assignee: Freescale Semiconductor, Inc., Austin, TX (US)

(21) Appl. No.: 14/479,377

(22) Filed: Sep. 8, 2014

(51) Int. Cl. H01L 23/498; H05K 3/34; H01L 21/52; H05K 1/18; H01L 23/31; H01L 21/48

(52) U.S. Cl. CPC H01L 23/49827; H01L 23/49838; H01L 23/3157; H01L 23/49811; H01L 21/486; H01L 21/4853; H01L 21/52; H05K 1/181; H05K 3/341; H05K 2201/10378; H05K 2201/1053

(57) ABSTRACT

A method for forming a pass-through layer of an interposer of a packaged semiconductor device in which conducting structures are extended between first and second ends of a casing. The conducting structures are subsequently encapsulated in a molding compound to form a molded bar, and the molded bar is sliced to obtain the pass-through layer. The pass-through layer has conducting vias, each corresponding to a sliced section of one of the conducting structures. The cost of pass-through layers formed in this manner may be less than that of comparable silicon or glass pass-through layers.

### BACKGROUND

The present invention relates generally to semiconductor integrated circuit packaging, and, more particularly, to interposers used in packaged semiconductor devices.

In a conventional 2.5D packaged semiconductor device, one or more integrated circuit (IC) dies are mounted on a glass or silicon interposer that, in turn, is mounted on a package substrate. The glass or silicon interposer provides electrical connections between the dies and the package substrate, and possibly between the dies themselves. The cost of manufacturing glass and silicon interposers is relatively high. Therefore, there is a need for lower-cost methods of fabricating these package components.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 shows a cross-sectional side view of a 2.5D packaged semiconductor device comprising a molded interposer according to one embodiment of the present invention;

FIG. 2 is a simplified flow chart of a method of fabricating the molded interposer of FIG. 1 according to one embodiment of the present invention;

FIG. 3 shows a perspective view of a casing according to one embodiment of the present invention used to secure the wires of FIG. 1;

FIGS. 4A and 4B are perspective views of a mold in open and closed positions, respectively, according to one embodiment of the present invention, and having the casing of FIG. 3 positioned therein;

FIG. 5 is a perspective view of a molded bar according to one embodiment of the present invention being sawn into multiple instances of the pass-through layer of FIG. 1;

FIG. 6 is a cross-sectional side view of a pass-through layer according to one embodiment of the present invention with bond pads formed thereon; and

FIG. 7 is a top view of a reconstituted wafer form of interposers according to one embodiment of the present invention.

### DETAILED DESCRIPTION

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the present invention.

In the following description, it will be understood that certain embodiments of the present invention are directed to molded interposers, methods of manufacturing molded interposers, and packaged semiconductor devices assembled with molded interposers. For ease of discussion, one particular embodiment of a packaged semiconductor device having a particular configuration is shown and discussed in detail. It will be understood that interposers of the present invention may be used with package configurations other than that shown.

In one embodiment of the present invention, an apparatus comprises an interposer for a packaged semiconductor device. The interposer comprises a pass-through layer and a first redistribution layer. The pass-through layer comprises (i) a first surface and a second surface parallel to the first surface, (ii) a plurality of conducting vias extending between the first surface and the second surface, and (iii) molding compound encapsulating the conducting vias. The first redistribution layer abuts the first surface of the pass-through layer.

Another embodiment of the present invention is a method for forming a pass-through layer of an interposer of a packaged semiconductor device. In the method, conducting structures are extended between first and second ends of a casing. The conducting structures are subsequently encapsulated in a molding compound to form a molded bar, and the molded bar is sliced to obtain the pass-through layer. The pass-through layer comprises a plurality of conducting vias, each conducting via corresponding to a sliced section of one of the conducting structures.

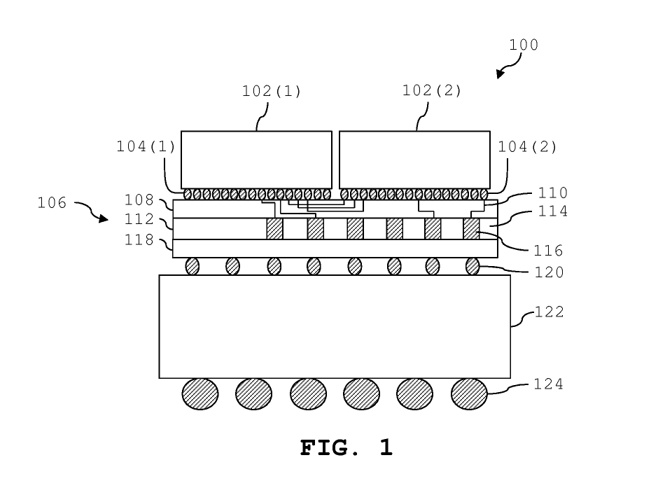

FIG. 1 shows a cross-sectional side view of a 2.5D packaged semiconductor device 100 comprising a molded interposer 106 according to one embodiment of the present invention. The device 100 comprises two integrated circuit (IC) dies 102(1) and 102(2), the function of which may vary depending on the particular application in which the device 100 is implemented. Methods of fabricating IC dies such as IC dies 102(1) and 102(2) are well known, and therefore not described herein.

The IC dies 102(1) and 102(2) are mounted onto, and electrically coupled to, the molded interposer 106 via flip-chip bumps 104(1) and 104(2), respectively. The molded interposer 106 provides a fan-out from the relatively closely-spaced flip-chip bumps 104(1) and 104(2) of the IC dies 102(1) and 102(2), respectively, to solder bumps 120 on the bottom of the molded interposer 106 that are spaced further apart than the flip-chip bumps 104(1) and 104(2). The molded interposer 106 may also electrically interconnect flip-chip bumps 104(1) of IC die 102(1) with flip-chip bumps 104(2) of the IC die 102(2).

The molded interposer 106 comprises a top-side redistribution layer (RDL) 108, a pass-through layer 112, the solder bumps 120 and, optionally, a bottom-side redistribution layer 118. The top-side redistribution layer 108, which may be built up in layers using, for example, photolithography techniques, comprises a plurality of metal traces 110 that interconnect the IC dies 102(1) and 102(2) to conducting vias 116 in the pass-through layer 112, and optionally, to one another. The bottom-side redistribution layer 118 (if implemented) may also be fabricated using photolithography techniques and may comprise a plurality of metal traces (not shown) that interconnect the vias 116 to the solder bumps 120.

The pass-through layer 112, the fabrication of which is described in further detail below, comprises vias 116 encapsulated in a molding compound 114. The vias 116 may be metal wires, carbon fibers, carbon nano-tube (CNT) fibers, the like, or combinations thereof. The molding compound 114 may be a plastic (e.g., a thermo-setting plastic), an epoxy, a silica-filled resin, a halide-free material, the like, or combinations thereof.

The solder bumps 120 electrically and mechanically connect the interposer 106 to a package substrate 122. In this embodiment, the device 100 is a ball-grid array (BGA) device comprising a plurality of solder balls 124 formed on the bottom of the package substrate 122. In alternative embodiments, other packaging technologies (e.g., pin-grid array technology) may be used. The solder balls 124 are used to connect the device 100 to a package-external device (e.g., a printed circuit board) (not shown), and the spacing of the solder balls 124 is selected to match that of the package-external device.

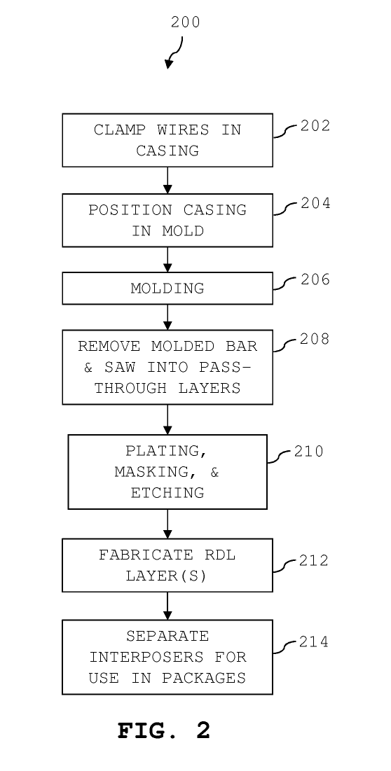

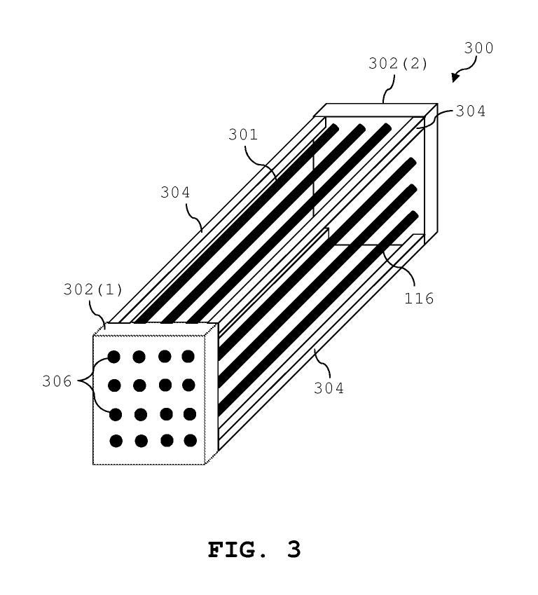

FIG. 2 shows a simplified flow chart of a method 200 for fabricating the molded interposer 106 of FIG. 1 according to one embodiment of the present invention. To further understand the steps of the method 200, consider FIGS. 3-7 along with FIG. 2.

In step 202, conducting wires (e.g., metal wires, carbon fibers, carbon nano-tube (CNT) fibers, etc.) used to form the vias (e.g., 116 in FIG. 1) are mounted into a casing that secures the wires in position for molding.

FIG. 3 shows a perspective view of a casing 300 according to one embodiment of the present invention used to secure wires 301. The casing 300 has first and second ends 302(1) and 302(2), which are separated by bars 304. Each end 302(1) and 302(2) has a plurality of holes 306 formed therein for receiving the ends of the wires 301. Note that FIG. 3 shows one pattern of the holes 306; however, other patterns are possible according to alternative embodiments of the present invention. The wires 301 are pulled taut between the ends 302(1) and 302(2) to prevent the wires 301 from contacting one another and to keep the wires at designated locations and pitch in the final sawn interposer.

In step 204, the casing with wires is positioned into a cavity of a mold, and in step 206, molding is performed.

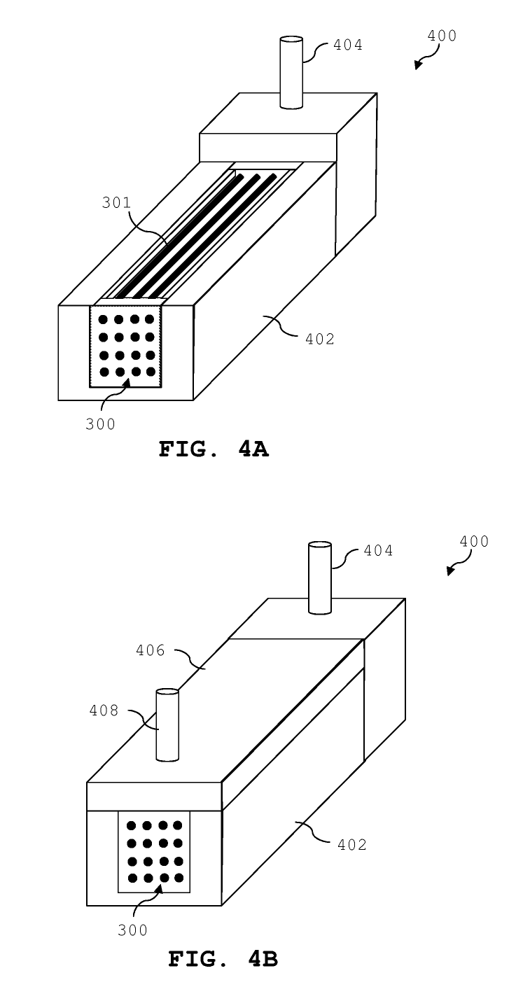

FIGS. 4A and 4B show perspective views of a mold 400 in open and closed configurations, respectively, according to one embodiment of the present invention, and having the casing 300 positioned therein. The casing 300 is positioned such that the wires 301 extend parallel to the general direction that the molding compound (not shown) flows into the mold 400. This reduces the likelihood that the force of the molding compound flowing into the mold 400 will cause the wires 116 to contact one another.

With the casing 300 in place, the mold 400 is closed by positioning an upper mold portion 406 on the lower mold portion 402. Molding compound is then injected into the mold 400 via an injection gate 404 to encase the wires 301. In at least some embodiments, the molding compound may be a pellet or liquid that is positioned in a transfer pot (not shown). The pellet or liquid may then be heated, and a plunger may force the resulting softened or liquid molding compound from the transfer pot into the injection gate 404.

In step 208, the casing is removed from the mold, the resulting molded bar comprising the wires is removed from the casing, and the molded bar is sawn into individual pass-through layers having vias 116.

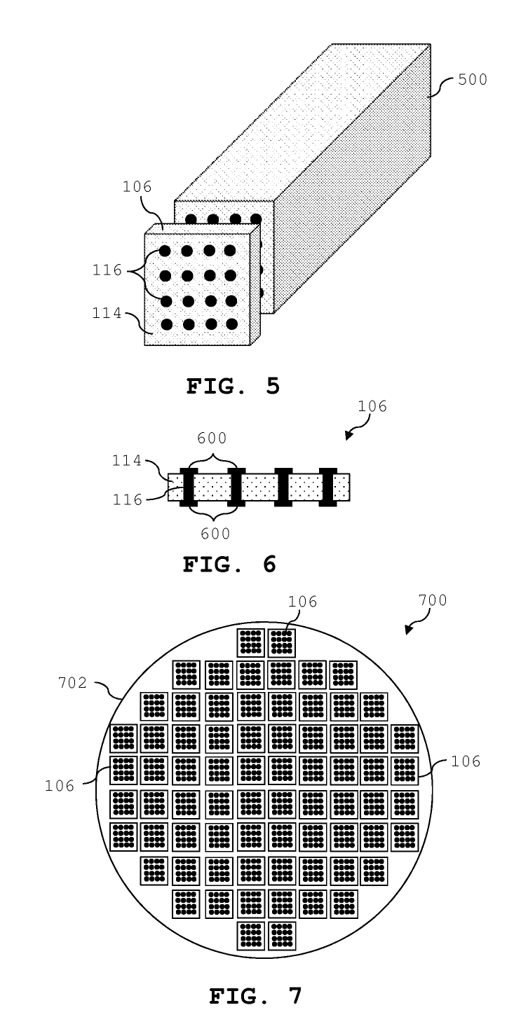

FIG. 5 shows a perspective view of a molded bar 500 according to one embodiment of the present invention being sawn into multiple instances of the pass-through layer 106 of FIG. 1.

In step 210, plating (e.g., electroless or electrolytic) is performed on the upper and lower surfaces of each pass-through layer, and masking and etching are performed to form bond pads on the ends of the vias of the pass-through layer.

FIG. 6 shows a cross-sectional side view of a pass-through layer 106 according to one embodiment of the present invention with bond pads 600 formed thereon.

In step 212, redistribution layers are formed on the top sides of the pass-through layer and, optionally, on the bottom sides of the pass-through layer the individual pass-through layers. To support formation of the redistribution layers, the individual pass-through layers may be assembled into the form of a reconstituted wafer by adhering the pass-through layers onto a carrier.

FIG. 7 shows a top view of a reconstituted wafer 700 according to one embodiment of the present invention formed by adhering a plurality of pass-through layers 106 onto a carrier 702.

After adhering the individual pass-through layers 106 onto the carrier 702, the reconstituted wafer 700 may be over-molded to form a molded sub-assembly (not shown) that is subsequently detached from the carrier 702. Redistribution layers may then be formed on the top (and optionally, bottom) sides of the pass-through layers on the detached molded sub-assembly. Each redistribution layer is built up with dielectric and metal layers and may be formed using the same processing (e.g., photolithography) and machinery that is used to form the redistribution layers in prior-art silicon interposers. In step 214, the resulting interposers are separated from one another for use in assembling packaged semiconductor devices such as device 100 of FIG. 1. The interposers may be separated using, for example, a saw.

Although the FIG. 1 shows an embodiment in which the IC dies 102(1) and 102(2) are electrically connected to the interposer 106 using flip-chip bumps 104(1) and 104(2), embodiments of the present invention are not so limited. According to alternative embodiments of the present invention, IC dies may be electrically connected to an interposer using bond wires.

Further, although FIG. 1 shows an embodiment comprising two IC dies 102(1) and 102(2) that are side-by-side, embodiments of the present invention are not so limited. According to alternative embodiments, packaged semiconductor devices of the present invention may comprise as few as one die or more than two dies. Further, according to alternative embodiments, packaged semiconductor devices of the present invention may comprise dies that are in a stacked relation.

Yet further, although FIG. 5 shows a pass-through layer 106 having a rectangular cross-section, embodiments of the present invention are not so limited. According to alternative embodiments, the pass-through layer (and interposer for that matter) may have a shape other than a rectangle (e.g., a circle).

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Terms of orientation such as “lower,” “upper,” “horizontal,” “vertical,” “above,” “below,” “up,” “down,” “top,” “bottom,” “right,” and “left” well as derivatives thereof (e.g., “horizontally,” “vertically,” etc.) should be construed to refer to the orientation as shown in the drawing under discussion. These terms of orientation are for convenience of description and do not require that the apparatus be constructed or operated in a particular orientation.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

1-4. (canceled)

5. A method of assembling a semiconductor device, comprising:
(a) extending, in a casing comprising a first end and a second end, a plurality of conducting structures between the first and second ends;
(b) encapsulating the conducting structures in a molding compound to form a molded bar;
(c) slicing the molded bar to obtain a pass-through layer for an interposer of a packaged semiconductor device, wherein the pass-through layer comprises a plurality of conducting vias, each conducting via corresponding to a sliced section of one of the conducting structures, a first surface, and a second surface parallel to the first surface, wherein each of the conducting vias extends between the first and second surfaces; and
(f) masking and etching the pass-through layer to form bond pads on the first and second surfaces.

6. The method of claim 5, wherein step (c) comprises slicing the molded bar multiple times to obtain a plurality of pass-through layers for a plurality of interposers of a plurality of packaged semiconductor devices.

7. The method of claim 5,
further comprising (d) forming the interposer by depositing a first redistribution layer on the first surface of the pass-through layer.

8. The method of claim 7, further comprising (e) depositing a second redistribution layer on the second surface of the pass-through layer.

9. The method of claim 7, further comprising (e) forming a plurality of conducting leads on a bottom surface of the interposer.

10. The method of claim 7, wherein step (d) comprises:
(d1) assembling the pass-through layer and a plurality of other pass-through layers into a reconstituted wafer form; and
(d2) forming an instance of the first redistribution layer on each of the pass-through layer and the other pass-through layers while the pass-through layer and plurality of other pass-through layers are in the reconstituted wafer form.

11. The method of claim 10, further comprising (e) assembling the packaged semiconductor device, wherein step (e) comprises:
(e1) mounting at least one integrated circuit (IC) die onto the interposer and electrically coupling the IC die to one or more of the conducting vias; and
(e2) mounting the interposer onto a substrate and electrically coupling one or more of the plurality of conducting vias to the substrate.

12. A packaged semiconductor assembled using the method of claim 5.
